(19) United States
(12) Patent Application Publication
(10) Pub. No.: US 2007/0178683 A1
(43) Pub. Date: Aug. 2, 2007

(54) Semiconductive device fabricated using a two step approach to silicide a gate and source/drains

(75) Inventors: Manfred B. Ramin, Austin, TX (US); Mike F. Pas, Richardson, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/346,126

(22) Filed: Feb. 2, 2006

(51) Int. Cl. H01L 21/44

(52) U.S. Cl. 438/586; 438/592; 438/664; 438/682

(57) ABSTRACT

In one aspect, the invention provides a method of fabricating a semiconductive device [200], comprising siliciding a gate [340] with a first silicidation layer [710], removing a protective layer [510] to expose source/drains [415], and siliciding the gate [340] and the source/drains [415] with a second silicidation layer.

### TECHNICAL FIELD OF THE INVENTION

The invention is directed in general to a semiconductive device, and more specifically, to a semiconductive device fabricated using a two step approach to silicide a gate and source/drains.

### BACKGROUND

Metal gate electrodes are currently being investigated to replace polysilicon gate electrodes in today's ever shrinking and changing transistor devices. One of the principle reasons the industry is investigating replacing the polysilicon gate electrodes with metal gate electrodes is to solve problems of poly-depletion effects and boron penetration for future CMOS devices. Traditionally, a polysilicon gate electrode with an overlying silicide was used for the gate electrodes in CMOS devices. However, as device feature sizes continue to shrink, poly depletion and gate sheet resistance become serious issues when using polysilicon gate electrodes. Accordingly, metal silicided gates have been proposed. In this approach, polysilicon is deposited over the gate. A metal is deposited over the polysilicon and reacted to completely consume the polysilicon, resulting in a substantially or fully silicided metal gate, rather than a deposited metal gate.

Complications can arise, however, during the silicidation of the gate electrodes. For example, in some conventional processes, where the gate is silicided before the source/drains are activated, the gates suffer from potential work function drift because of potential degradation of the gate dielectric/gate interface upon exposure to high thermal budgets (e.g., those in excess of 900° C.) that are required to activate the source/drains. When the gate is silicided before the source/drain activation, the high activation temperatures can drive the silicide through the gate dielectric and into the channel region.

To overcome this problem, other processes, where the gate electrodes are silicided after the activation of the source/drain, have been developed. In one such process, two different silicidation steps are performed with one thicker metal being used to silicide the gate electrode and a thinner metal being used to separately silicide the source/drains. Though these processes address the problems associated with those processes where the gate is silicided before the source/drain activation, they require several different process steps. These steps include separately masking the source/drains and the gate electrodes to protect them during their respective silicidation processes and using an expensive chemical/mechanical polishing processes to remove the masks. These steps not only add cost and time to the manufacturing process, but they do not fully address the above-mentioned problems.

In other processes, the source/drains are silicided before the gate electrodes. Given the difference in the thickness of the gate electrode and the source/drain junction depth, the silicide in the source/drains is driven deeper to the point of penetrating the source/drain junction, during the silicidation of the gate. This can render the device inoperable, cause shorts, or spikes in the device. Also, some conventional processes include the option to use different metals for the gate and source/drains, which uses one masking step, but the first metal has to suffer the additional heat budget of the second metals silicidation, which limits the use to only a few metal combinations.

Accordingly, what is needed in the art is a silicidation process that avoids the deficiencies of the conventional processes discussed above.

### SUMMARY OF INVENTION

To overcome the deficiencies in the prior art, the invention, in one embodiment, provides a method of fabricating a semiconductive device, comprising siliciding a gate with a first silicidation layer, removing a protective layer to expose source/drains, and siliciding the gate and the source/drains with a second silicidation layer.

In another embodiment, the invention provides a method of manufacturing a semiconductive device, comprising forming gates over a semiconductive substrate, forming source/drains adjacent the gates, and siliciding the gates and the source/drains. In this embodiment, siliciding the gates and the source/drains comprise siliciding the gates with a first silicidation layer, removing a protective layer to expose the source/drains, and siliciding the gate and the source/drains with a second silicidation layer. The method of manufacturing the semiconductive device further comprises forming dielectric layers over the gates and forming interconnects in the dielectric layers to interconnect the gates and form an operative integrated circuit.

### BRIEF DESCRIPTION OF THE DRAWINGS

The invention is best understood from the following detailed description when read with the accompanying FIGUREs. Reference is now made to the following descriptions taken in conjunction with the accompanying drawings, in which:

FIG. 1 illustrates a sectional view of one embodiment of a semiconductive device provided by the invention;

FIG. 2 illustrates a sectional of the semiconductive device at an early stage of manufacture;

FIG. 3 illustrates a sectional view of the semiconductive device of FIG. 2 following gate patterning;

FIG. 4 illustrates a sectional view of semiconductive device of FIG. 3 following spacer and source/drain formation;

FIG. 5 illustrates a sectional view of the semiconductive device of FIG. 4 following deposition of the protective layer;

FIG. 6 illustrates a sectional view of the semiconductive device of FIG. 5 following the partial removal of the protective layer;

FIG. 7 illustrates a sectional view of the semiconductive device of FIG. 6 following deposition of a silicidation layer;

FIG. 8 illustrates a sectional view of the semiconductive device of FIG. 7 following a silicidation anneal;

FIG. 9 illustrates a sectional view of the semiconductive device of FIG. 8 following the removal of the remaining portion of the protective layer;

FIG. 10 illustrates a sectional view of the semiconductive device of FIG. 9 following the deposition of another silicidation layer;

FIG. 11 illustrates a sectional view of the semiconductive device of FIG. 10 following another silicidation anneal;

FIG. 12 illustrates a sectional view of the semiconductive device of FIG. 11 following the silicidation of the gate and formation of the silicided source/drain contacts; and

FIG. 13 illustrates a sectional view of an integrated circuit (IC) incorporating the semiconductive device.

### DETAILED DESCRIPTION

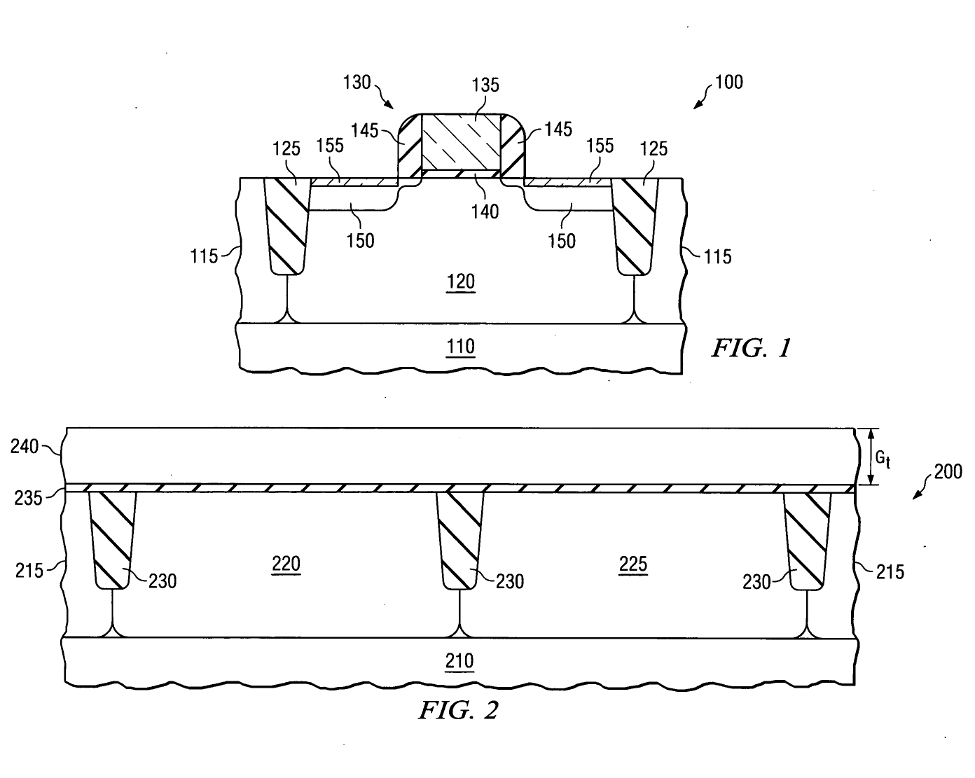

FIG. 1 is one embodiment of a semiconductive device 100 of the invention. The semiconductive device 100 may comprise a conventional semiconductive substrate 110, such as a wafer. An active region 115, which may also be conventional, is located over the substrate 110, and includes a well 120 that can be conventionally formed. The well 120 is typically located adjacent another well that is similarly or complementary doped. Isolation structures 125, such as shallow trenches, are also located in the active region 115 and electrically isolate adjacent wells 120. The isolation structures 125 may be conventionally formed and filled with a conventional dielectric material, such as a high density plasma oxide.

The semiconductive device 100 further includes a transistor 130 that includes a silicided gate 135, a gate dielectric 140, oxide spacers 145, source/drains 150 and silicide contacts 155 located over the source/drains 150, all of which may be constructed with conventional materials and processes. Because of the way in which the silicide contacts 155 are formed, the gate 135 can be substantially silicided without the silicide penetrating the source/drain junction, thereby avoiding the problems associated with the above-mentioned conventional processes. Those who are skilled in the art will understand what defines the source/drain junction. As used herein, a gate is substantially silicided when at least 60% of the volume of the gate 135 contains a silicide. In another embodiment, the gate 135 may be fully silicided; that is the silicide is located within just a few (3 to 4) atomic layers distance from or right at the interface with the gate dielectric 140. Different embodiments that may be used to manufacture the semiconductive device 100 are discussed below.

FIG. 2 shows the semiconductive device 100 of FIG. 1 at an early stage of manufacture. The semiconductive device 200 includes a semiconductive substrate 210, such as silicon, silicon-germanium, or gallium arsenide, over which is located an active layer 215. The active layer 215 may be a portion of the substrate 210 that is appropriately doped, or it may be a conventionally doped epitaxial layer. Wells 220 and 225 are formed within the active layer 215 and are electrically isolated by isolation structures 230. The wells 220 and 225 may be similarly doped with conventional p-type or n-type dopants, or they may be oppositely doped to a complementary configuration. A high quality gate dielectric layer 235 is located over the active layer 215, and a gate layer 240, such as a polysilicon layer is located over the gate dielectric layer 235, both of which may be constructed by conventional processes. The gate layer 240 may be doped with a dopant, such as boron, phosphorous, arsenic or another similar dopant, depending on whether the semiconductive device 200 is operating as a PMOS device, an NMOS, or CMOS device. The gate layer 240 is doped to configure it to the minimum energy required to bring an electron from the Fermi level to the vacuum level or further adjust its work function. The thickness of the gate layer 240 may vary, depending on design. In one example, the thickness of the gate layer 240 may range from about 100 nm to about 40 nm, but other thicknesses are also applicable.

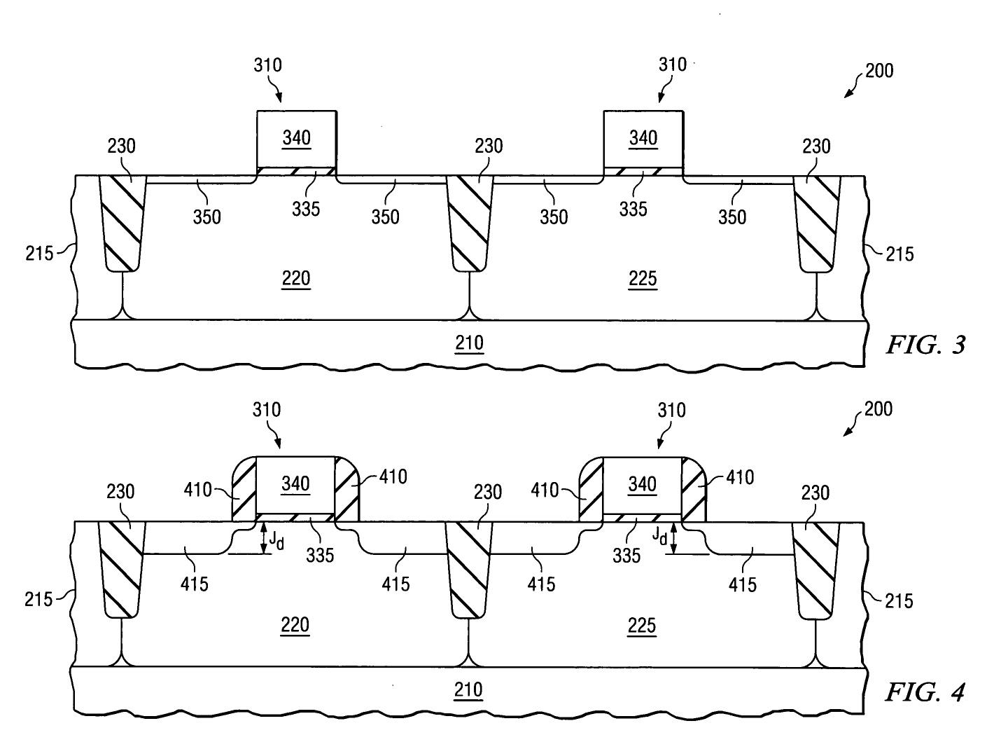

In FIG. 3, the layers 235 and 240 have been conventionally patterned to form gate electrodes 310 that include gate dielectrics 335 and gates 340. The semiconductive device 200 further includes lightly doped drains (LDD) 350, which may be conventional. In other embodiments, however, the LDDs 350 may not be present.

FIG. 4 illustrates the semiconductive device 200 of FIG. 3 after the formation of spacers 410 that may also be of conventional design. The spacers 410 may be comprised of a single deposited material, such as an oxide, or it may have a multi-layered configuration. For example, the spacers 410 may be a combination of oxide, nitride, and oxide. The spacers 410 are used to offset the deep source/drains 415 from the edge of the gates 340 by the desired distance. The source/drains 415 are appropriately doped to form a PMOS, NMOS, CMOS device, or combinations thereof.

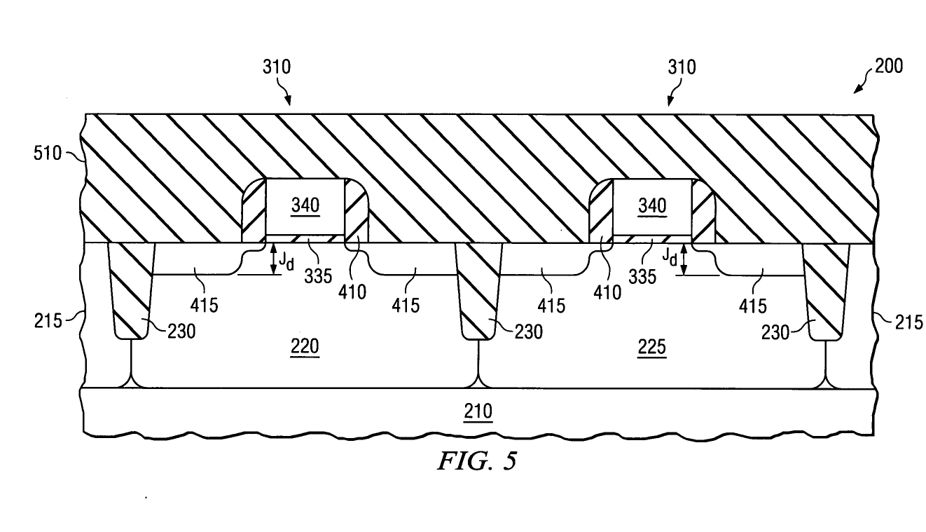

FIG. 5 shows the semiconductive device 200 of FIG. 4 after the formation of a protective layer 510 over the gates 340 and source/drains 415. The protective layer 510 protects the source/drains 415 from silicidation during an initial silicidation of the gates 340. In one embodiment, the protective layer 510 may be a conventionally deposited oxide layer. The thickness of the protective layer 510 varies, but in one embodiment, the thickness may be about 300 nm. Otherwise, the thickness should be sufficient to adequately protect the source/drains 415, during the initial silicidation of the gates 340. The protective layer 510 may be achieved from well known high density plasma deposition processes or chemical vapor deposition processes. One example of such a deposition process involves the use of chemical vapor deposition to form the protective layer 510. Non-limiting examples of materials that form the protective layer 510 include silicon dioxide, fluorosilicate glass, borophosphorosilicate, or spin on glass (SOG). In one embodiment, the protective layer 510 is blanket deposited to a substantial thickness. As shown, the protective layer 510 fills in the regions between gates 340 in which the source/drains are located to protect them from subsequent processing steps.

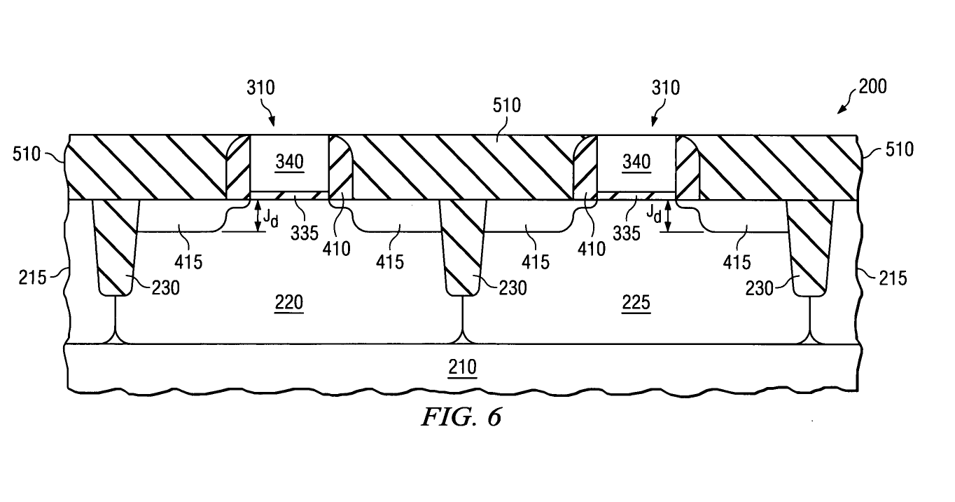

In the embodiment illustrated in FIG. 6, a portion of the protective layer 510 is removed to expose the upper surface of the gates 340. One aspect of the invention provides a process wherein a conventional chemical/mechanical process is conducted to remove the protective layer 510 down to within about 20 nm before reaching the upper surface of the gates 340. At this point, the method of removal may be changed to a conventional wet etch process or a dry plasma process. The wet etch and plasma processes provide better control over the removal of the last 20 nm or so of the protective layer 510. Upon the completion of the removal process, the upper surfaces of the gates 340 are adequately exposed.

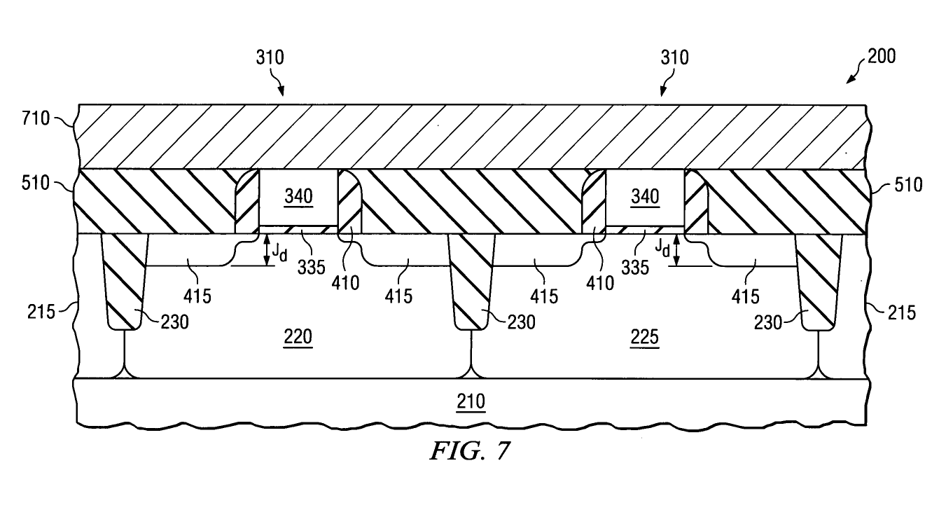

FIG. 7 is the semiconductive device 200 of FIG. 6 following the deposition of a silicidation layer 710, which may be deposited with conventional processes. Here, a silicidation layer 710 is the layer that is deposited and is used to silicide the underlying layer or layers. The silicidation layer 710 may be any conventional metal, metal alloy, silicide layer, or any other material that can be used to silicide the gates 340. The silicidation layer 710 is used to further adjust or tune the work function of the gates 340, and the metal, metal alloy, or other selected material will vary, depending on the desired work function. Non-limiting examples of the types of materials that can be used to silicide the gates 340 include nickel, cobalt, or tungsten.

The thickness of the silicidation layer 710 may vary. For example, in one embodiment, the thickness of the silicidation layer 710 may be equal to the difference between what is required to at least substantially, or alternatively, fully silicide the gates 340 and the amount required to silicide the source/drain 415 without punching through the junction of the source/drain 415. In one specific example, the thickness of the silicidation layer 710 may range from about 30 nm to about 40 nm where the thickness needed to silicide the source/drains 415 ranges from about 30 nm to about 40 nm. It should be understood, however, that these ranges depend on the actual gate thickness and the source/drain junction and is most applicable for NMOS and doped PMOS. Further, since the PMOS could also be formed using Ni rich silicide rather than a dopant, the gate thickness would be chosen thinner in the PMOS device, which would change the stated ranges. Given this understanding, those skilled in the art would understand how to change the ranges accordingly.

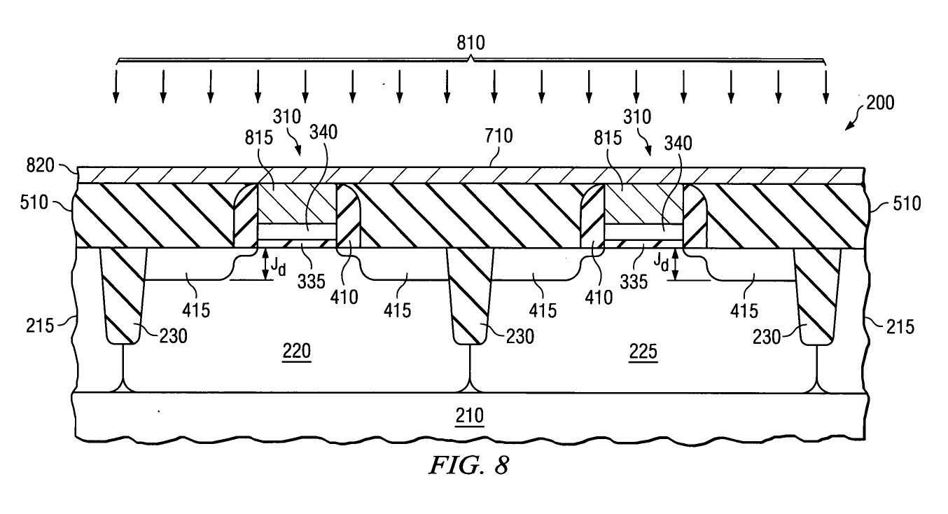

Following the deposition of the silicidation layer 710, the semiconductive device 200 in FIG. 8 is subjected to a thermal anneal 810 at a temperature that ranges from about 300° C. to about 450° C. and for a period of time ranging from about 30 seconds to about 120 seconds, and in other embodiments, the time will range from about 30 seconds to about 60 seconds. It should be noted, however, that the silicidation process may vary depending on the amount of silicidation that is desired and the materials or metals that are used to silicide the gates 340. For example, if the gates 340 are silicided with nickel, then the silicidation process parameters used will be about 300° C. to about 400° C. for a time ranging from about 30 seconds to about 60 seconds. Those who are skilled in the art will understand how to achieve the desired degree of silicidation when using various materials.

In one embodiment, anneal 810 forms a metal rich phase 815 located in an upper portion of the gates 340, as illustrated in FIG. 8. For example, where the silicidation metal is nickel, the upper portion of the gates 340 may include forms of nickel rich silicide, such as Ni₂ and richer along with the nickel. Depending on the initial thickness of the silicidation layer 710, anneal 810 may leave a portion 820 of the silicidation layer 710 remaining over the semiconductive device 200, as illustrated. In other embodiments, the silicidation layer 710 may be fully consumed. The remaining portions of the protective layer 510 protect the source/drains 415 from the silicidation anneal 810 at this point in the process. Following anneal 810, any portion 820 of the silicidation layer 710 that remains may be conventionally removed.

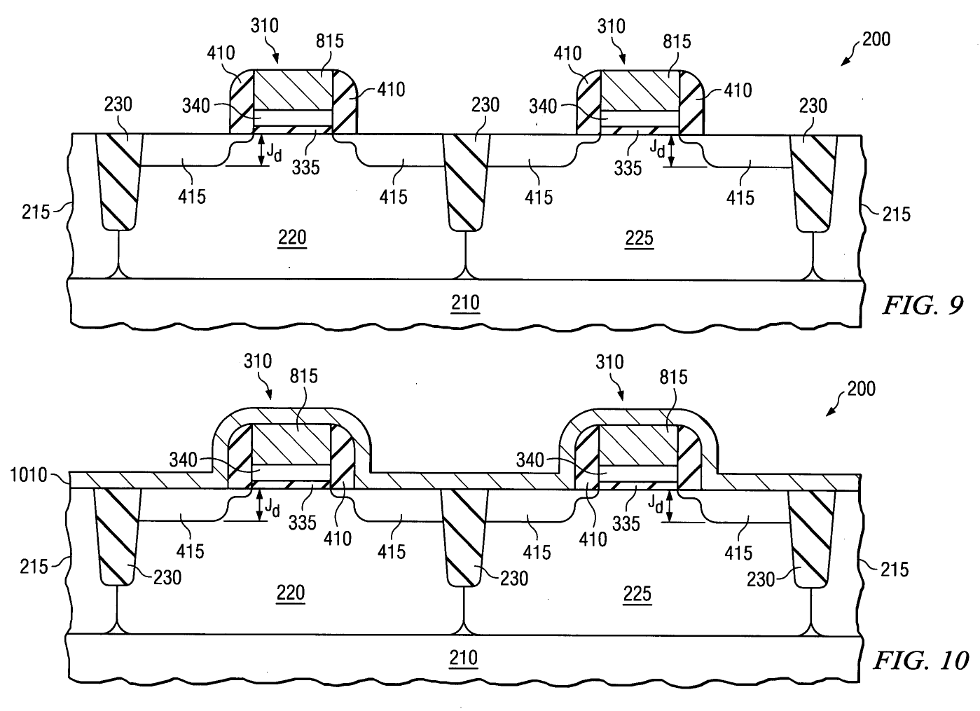

As illustrated in FIG. 9, upon completion of the partial silicidation of the gates 340, the remaining portions of the protective layer 510 may be conventionally removed, using for example, a hydrofluoric wet etch that exposes the source/drains for a subsequent silicidation process.

In FIG. 10, another silicidation layer 1010 may be conventionally deposited. As seen here, the upper surface of the gates 340 remain unprotected, and the silicidation layer 1010 covers the exposed upper surface of the gates 340 and the source/drains 415. The thickness of the silicidation layer 1010 will be whatever is required to complete the silicidation of the gates 340 without punching through the junction of the source/drains 415 or otherwise over-siliciding the source/drains 415; that is the silicidation should not substantially inhibit the function of the source/drains 415. In most embodiments, the silicidation layer 1010 will comprise the same material as the silicidation layer 710 introduced in FIG. 7. However, the material that is used may be different to give further flexibility in achieving a desired work function. As stated above, the thickness of the silicidation layer 1010 may range from about 30 nm to about 40 nm.

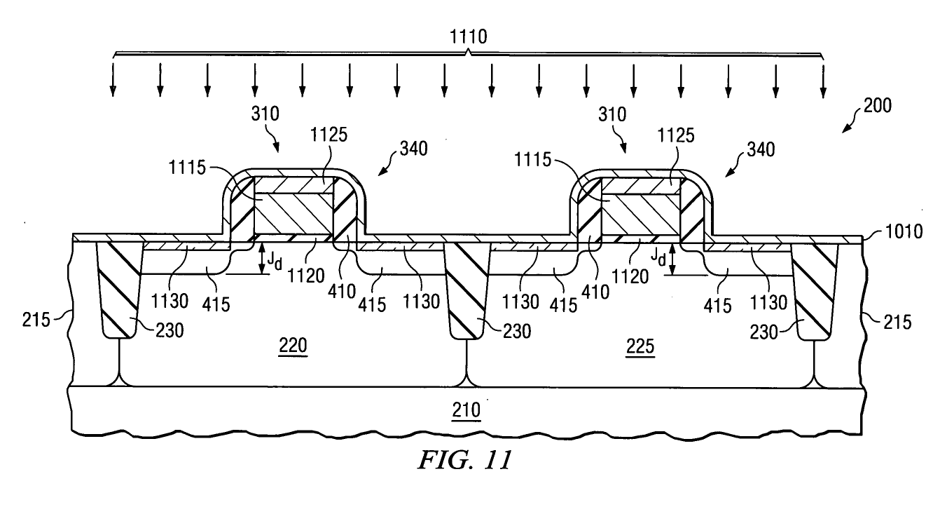

As seen in FIG. 11, following the deposition of the silicidation layer 1010, the semiconductive device 200 is subjected to another anneal 1110 that, in one embodiment, is conducted at a temperature ranging from about 450° C. to about 550° C. for about a period of time ranging from about 20 second to about 60 seconds, and in one embodiment, the period of time is for 30 second. Again, these parameters may vary depending on the materials or metals used and the extent of silicidation that needs to be achieved to substantially silicide the gate 340. Anneal 1110 drives additional metal into the gates 340 and into the source/drains 415. The anneal 1110, in one embodiment, will complete the silicidation of the gates 340. In one aspect of the invention, as anneal 1110 drives the metal further into the gates 340 and initially into the source/drains 415, the previously discussed metal rich phase 815 becomes a mono-silicide 1115 within the gates 340 and the source/drains 415. As the mono-silicide 1115 is formed in the gates 340 and driven toward the gate/gate dielectric interface 1120, it is replaced with metal from the silicidation layer 1010 to form metal rich regions 1125 in the upper portion of the gates 340, while mono-silicided contacts 1130 are formed in the source/drains 415. Thus, the gates contain both a mono-silicided region and a metal rich silicide region. In one advantageous embodiment where the gate is an NMOS gate, a portion of the layer should be metal rich to ensure full silicidation of the gate. If there is no excess Ni, incomplete silicidation may result. In those instances where the gate is a PMOS gate, the PMOS gate could be metal-rich thru the whole gate. This could be achieved by either reducing the thickness of the gate or by increasing the thickness of the silicidation layer 710, or by conducting both of these steps.

As seen in FIG. 11, after silicidation is complete, the silicidation within the source/drains 415 has not penetrated any portion of the source/drains 415 junctions. Moreover, it should be noted that the source/drains 415 have a silicide thickness that is thinner, for example, from 30 to 40 nm thinner, than the thickness of the gates 340.

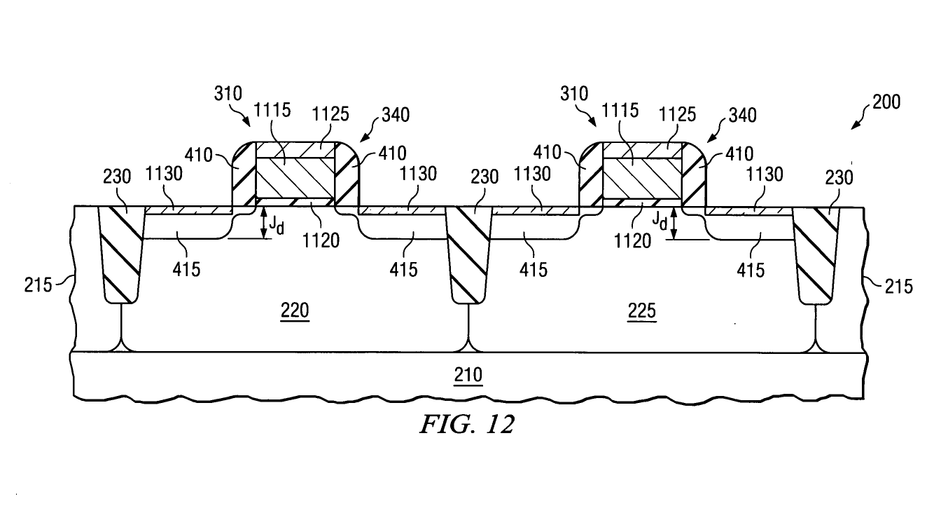

Depending on the thickness of the silicidation layer 1010 and the anneal temperatures and times, in some embodiments, a portion of the silicidation layer 1010 may remain, as shown in FIG. 11. In other embodiments, however, the silicidation layer 1010 may be fully consumed in siliciding the gates 340 and the silicide contacts 1130. After anneal 1110 is completed, any remaining portion of the silicidation layer 1010 is conventionally removed, which leaves the silicided gates 340 and silicided contacts 1130, as shown in FIG. 12. At this point, those who are skilled in the art would understand how to complete the fabrication of the semiconductive device.

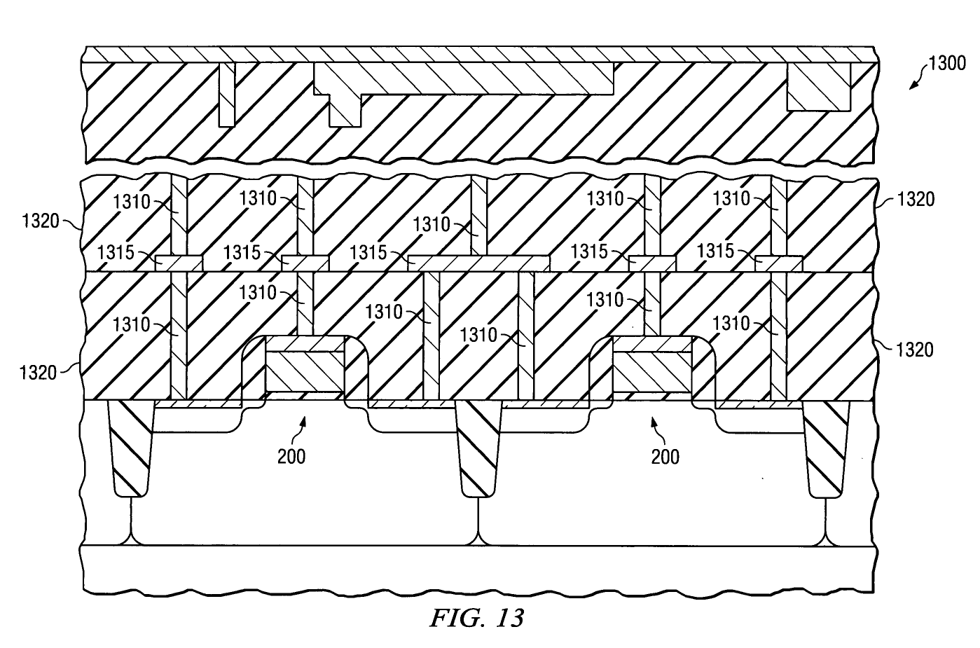

FIG. 13 is an integrated circuit (IC) 1300 that incorporates the completed semiconductive device 200 of FIG. 12. The semiconductive device 200 may be configured into a wide variety of devices, such as CMOS devices, BiCMOS devices, Bipolar devices, as well as capacitors or other types of devices. The IC 1300 may further include passive devices, such as inductors or resistors, or it may also include optical devices or optoelectronic devices. Those skilled in the art are familiar with these various types of devices and their manufacture. The semiconductive device 200 includes the various components as discussed above, and interconnect structures 1310 and metal lines 1315, which may be fabricated using conventional materials and processes, electrically connect the components of the semiconductive device 200 to form an operative IC. The interconnect structures 1310 and metal lines 1315 may be formed in conventional dielectric layers 1320 that are located over the semiconductive device 200. The number of dielectric layers 1320 and metal lines 1315 will vary with design.

From the foregoing, it is seen that the invention provides a process that is less complex and involves fewer steps than the conventional processes described above. The lessened complexity is at least partially found in the fact that both the gates and the source/drain contacts are formed without requiring different masking steps in that the same silicidation layer that is used to silicide the source/drains is also used to complete the silicidation of the gates. Thus, fewer masking and removal steps are involved. This reduced complexity results is a more efficient and less costly manufacturing process. Though the protective layer is used in the present invention, it is easily formed by well known deposition techniques and requires no additional masks since it involves a blanket deposition of the material.

Those skilled in the art to which the invention relates will appreciate that other and further additions, deletions, substitutions, and modifications may be made to the described example embodiments, without departing from the invention.

What is claimed is:

1. A method of fabricating a semiconductive device, comprising:
siliciding a gate with a first silicidation layer;
removing a protective layer to expose source/drains; and
siliciding the gate and the source/drains with a second silicidation layer.

2. The method recited in claim 1, wherein siliciding with the first silicidation layer comprises siliciding at a first temperature and siliciding with the second silicidation layer comprises siliciding at a higher, second temperature.

3. The method recited in claim 2, wherein the first temperature ranges from about 300° C. to about 450° C. and the second temperature ranges from about 450° C. to about 550° C.

4. The method recited in claim 3, wherein the silicidation layer is subjected to the first temperature for a period of time ranging from about 30 seconds to about 120 seconds and is subjected to the second temperature for a period of time ranging from about 20 seconds to about 60 seconds.

5. The method recited in claim 1, wherein siliciding with the first silicidation layer comprises siliciding a portion of the gate and siliciding with the second silicidation layer comprises siliciding the source/drains and a remaining portion of the gate, simultaneously.

6. The method recited in claim 1, wherein the thickness of the second silicidation layer does not penetrate the source/drain junction.

7. The method recited in claim 1, wherein siliciding the gate with the first silicidation layer comprises forming a metal rich region within an upper portion of the gate.

8. The method recited in claim 1, wherein siliciding the gate with the first and second silicidation layers comprises forming a mono-silicide region adjacent the gate and a gate dielectric interface and a metal rich silicide region within an upper portion of the gate.

9. The method recited in claim 1, wherein the thickness of the first silicidation layer is greater than a thickness of the second silicidation layer.

10. The method recited in claim 1, wherein the total silicide thickness in the gate is greater than the silicide thickness in the source/drain.

11. The method recited in claim 1, wherein the first and second silicidation layers comprise metal.

12. The method recited in claim 1, further comprising depositing the protective layer over the gate and source/drains prior to siliciding with the first silicidation layer.

13. The method recited in claim 12 further comprising removing a portion of the protective layer to expose the gate prior to siliciding with the first silicidation layer.

14. A method of manufacturing a semiconductive device, comprising:
forming gates over a semiconductive substrate;
forming source/drains adjacent the gates;
siliciding the gates and the source/drains, comprising:
siliciding the gates with a first silicidation layer;
removing a protective layer to expose the source/drains; and
siliciding the gate and the source/drains with a second silicidation layer;
forming dielectric layers over the gates; and
forming interconnects in the dielectric layers to interconnect the gates and form an operative integrated circuit.

15. The method recited in claim 14, wherein siliciding with the first silicidation layer comprises siliciding at a first temperature and siliciding with the second silicidation layer comprises siliciding at a higher, second temperature.

16. The method recited in claim 15, wherein the first temperature ranges from about 300° C. to about 450° C. and the second temperature ranges from about 450° C. to about 550° C. and wherein the silicidation layer is subjected to the first temperature for a period of time ranging from about 30 seconds to about 60 seconds and to the second temperature for about 30 seconds.

17. The method recited in claim 14, wherein siliciding the gate with the first and second silicidation layers comprises forming a mono-silicide region adjacent the gate and a gate dielectric interface and a metal rich silicide region within an upper portion of the gate.

18. The method recited in claim 14, wherein the total silicide thickness in the gate is greater than the silicide thickness in the source/drain.

19. The method recited in claim 14, further comprising depositing the protective layer over the gates and source/drains prior to siliciding with the first silicidation layer and removing a portion of the protective layer to expose the gates prior to siliciding with the first silicidation layer.
